(19) United States
(12) Patent Application Publication
(10) Pub. No.: US 2002/0039835 A1
(43) Pub. Date: Apr. 4, 2002

(54) Method of depositing a conformal hydrogen-rich silicon nitride layer onto a patterned structure

(75) Inventors: Christophe Balsan, Vaux-le-Venil (FR); Corinne Buchet, Corbell Essonnes (FR); Patrick Raffin, Joinville le Pont (FR); Stephane Thioliere, Paris (FR)

Correspondence Address: International Business Machines Corporation, Margaret A. Pepper, Zip 482, 2070 Route 52, Hopewell Junction, NY, 12533, US

(73) Assignee: International Business Machines Corporation, Armonk, NY

(21) Appl. No.: 09/892,980

(22) Filed: Jun. 27, 2001

(30) Foreign Application Priority Data
Jul. 25, 2000 (EP) 0048007102203

(51) Int. Cl. H01L 21/44; H01L 21/31; H01L 21/469

(52) U.S. Cl. 438/597; 438/652; 438/653; 438/657; 438/775; 438/777; 438/778; 438/783; 438/784; 438/791; 438/792

(57) ABSTRACT

In the fabrication of EDRAM/SDRAM silicon chips with ground rules beyond 0.18 microns, a Si₃N₄ barrier layer is deposited onto the patterned structure during the borderless polysilicon contact fabrication. It is required that this layer be conformal and has a high hydrogen atom content to prevent junction leakage. These objectives are met with the method of the present invention. In a first embodiment, the Si₃N₄ layer is deposited in a Rapid Thermal Chemical Vapor Deposition (RTCVD) reactor using a NH₃/SiH₄ chemistry at a temperature and a pressure in the 600-950° C. and 50-200 Torr ranges respectively. In a second embodiment, it is deposited in a Low Pressure Chemical Vapor Deposition (LPCVD) furnace using a NH₃/SiH₂Cl₂ chemistry (preferred ratio 1:1) at a temperature and a pressure in the 640-700° C. and 0.2-0.8 Torr ranges respectively.

### FIELD OF THE INVENTION

The present invention relates to the manufacture of semiconductor integrated circuits (ICs) and more particularly to an improved method of depositing a conformal H-rich Si₃N₄ layer onto a patterned structure. Such a layer is appropriate for junction surface state passivation to reduce device junction leakage in embedded dynamic random access memory (EDRAM) and synchronous dynamic random access memory (SDRAM) silicon chips.

### BACKGROUND OF THE INVENTION

The deposition of silicon nitride (Si₃N₄) layers is an essential step in the fabrication process of borderless (doped) polysilicon contacts to prevent electrical fails (shorts, opens or junction leakage) that would be detrimental to the whole EDRAM/SDRAM silicon chip reliability. Si₃N₄ layers are extensively used to produce insulating spacers that act as a barrier to isolate the gate conductors from the doped polysilicon plugs which contact the diffusion (source/drain) regions of Insulated Gate Field Effect Transistors (IGFETs) and also as an etch stop.

In the manufacture of semiconductor integrated circuits and particularly in EDRAM/SDRAM silicon chips, a transfer IGFET and a storage capacitor are associated to form the one-device memory cell. For each IGFET in the array area, the source is connected to a doped polysilicon (or metal) contact which is part of a bit line, the drain is connected to one electrode (node) of the storage capacitor and the gate conductor forms the word line (it runs orthogonal to the bit line). It is of paramount importance to make sure that there is no electrical short between the polysilicon contact made with the diffusion region and the gate conductor. As a matter of fact, a total and reliable isolation is essential to the IGFET integrity and thus to the memory cell operation. Typically, the gate conductor consists of a composite doped polysilicon/metal silicide structure (the preferred metal is tungsten so that the metal silicide has a WSi_{X} like formulation). This total isolation is achieved by a dielectric material, usually Si₃N₄, which forms a protective cap atop the gate conductor and an insulating spacer on the gate conductor (GC) sidewall that are contiguous.

In the last generation of EDRAM/SDRAM silicon chips, due to scaling reduction effects, the dry etching process window is constantly reduced and consequently there is a serious risk of exposing said gate conductor sidewall during the formation of the contact hole to expose the diffusion region. As a result, there is created a serious risk of an electrical fail between gate conductors when said contact hole will be filled with a conductive material to form the contact with the diffusion region. Recently, a new contact hole structure named “borderless” and processes of efficiently making the same were developed to overcome this problem and meet the reliability specifications of this industry.

To date, the fabrication of borderless polysilicon contacts appears to be an absolute requirement for advanced EDRAM/SDRAM silicon chips and follow-on generations (256 Mbits and beyond). In particular, it requires the deposition of two Si₃N₄ layers, one will be used to form the insulating spacers, the other will be used later on both as a barrier and an etch stop during the borderless contact hole formation. This process step represents a major challenge for at least two reasons. First, it must avoid “opens” to ensure the lowest possible electrical resistance with the diffusion region and “shorts” between diffusion regions and gate conductors. Second, it must prevent any risk of junction leakage. Such electrical fails would be detrimental to the EDRAM/SDRAM silicon chip functionality. In addition, it is highly desirable that borderless polysilicon contacts are fabricated according to a simple and affordable process.

A conventional borderless polysilicon contact (CB) fabrication process is described hereinbelow in conjunction with FIG. 1 and FIGS. 2A-2F. All processing steps are conducted in the so-called MEOL module. (MEOL stands for Middle End Of the Manufacturing Line). It is important to point out that the illustrated layers in the drawings are not necessarily drawn to scale.

FIG. 1 schematically illustrates the initial structure referenced 10 which basically comprises a P-type doped silicon substrate 11 coated with a 4.5 nm thick silicon oxide (SiO₂) gate layer 12. In the substrate 11, two storage capacitors in their respective trenches are shown in the array area. On said SiO₂ gate layer 12, a composite conductive/insulating film has been formed. For instance, it is comprised of a bottom 80 nm thick phosphorus doped polysilicon layer 13, a 70 nm thick tungsten silicide (WSi_{X}) layer 14, and a 180 nm thick Si₃N₄ capping layer 15. Gate conductor lines 16 are formed by patterning these three layers using a conventional dry etch process, so that each gate conductor line 16 includes a Si₃N₄ cap still referenced 15 above the gate conductor. Finally, a 14 nm thick oxide layer 17 is formed by thermal oxidation as standard to passivate the gate conductor 13/14 sidewall to prevent any undesired oxidation during the subsequent hot temperature steps. As apparent in FIG. 1, the density of gate conductor lines 16 is greater in the “array” area (nested regions) than in the “support” area (isolated regions).

Still referring to FIG. 1, there are shown two diffusion regions 18′ and 18″ (generically 18) in the support and array areas respectively that were previously formed by ion implantation (arsenic and boron atoms for regions 18′ and phosphorous atoms for regions 18″) in the Front End Of Line (FEOL) module.

Now, turning to FIG. 2A, the conventional borderless polysilicon contact fabrication process starts with the conformal deposition of a Si₃N₄ layer 19 having a thickness of about 3 0 nm onto the patterned structure 10 top surface by LPCVD to form the insulating spacers. For instance, the Si₃N₄ material of layer 19 can be deposited in a TEL Fast Thermal Ramp, a tool manufactured by TOKYO ELECTRON Ltd (TEL), Tokyo, Japan using a NH₃/SiH₂Cl₂ (dichlorosilane: DCS in short) chemistry and the process parameters recited below.

| | |
|---|---|
| Pressure: | 150 mTorr |
| Temperature: | 780° C. |
| NH₃ flow: | 250 sccm |
| DCS flow: | 50 sccm |
| Duration: | 16 min |
| Wafer spacing: | 0.2 inch |

The target is to obtain this thickness of about 30 nm both on the top and the sidewall of gate conductor lines 16 measured on a product wafer in the support area.

After Si₃N₄ material deposition, an anisotropic dry etching step is then performed to pattern the Si₃N₄ layer 19 to form insulating spacers on the sidewall of GC lines 16. The etch step is stopped as soon as the SiO₂ gate layer 12 top surface is exposed at the bottom of the contact holes. For instance, this step may be conducted in the MxP+ chamber of an AME 5200 reactor, a tool commercially available from Applied Materials Inc., Santa Clara, Calif., USA, using a CHF₃/O₂/CO₂ chemistry, for instance, with the following operating conditions:

| | |
|---|---|
| Pressure: | 50 mTorr |
| Power: | 100 W |
| Temp. (Wall/Cath.): | 15/15° C. |
| He Cooling: | 26 Torr |
| CHF₃ flow: | 28 sccm |
| O₂ flow: | 6 sccm |
| CO₂ flow: | 75 sccm |
| Ar flow: | 50 sccm |
| Duration: | 75 s |

Si₃N₄ spacers still referenced 19 that are produced are shown in FIG. 2B. At this stage of the CB formation process, the wafer is submitted to a thickness measurement using an ellipsometer. Such a measurement is needed to evaluate the remaining thickness and uniformity of the Si₃N₄ cap 15 and SiO₂ gate layer 12. Next, a standard FM (Foreign Material) inspection is performed on the product wafer. Finally, a cleaning step is performed in a DNS wet bench, a tool manufactured by Dai Nippon Screen, Kyoto, Japan using a conventional wet process (deionized water rinse combined with ultrasonic waves).

Si₃N₄ spacers 19 will be now used to automatically delimit further implanted regions that are now required for smoothing junction profiles in the manufacture of advanced EDRAM/SDRAM silicon chips with 0.175 μm groundrules and beyond. To that end, a boron shallow implant is performed in a PI 9500 implanter, a tool manufactured by APPLIED MATERIALS Inc., Santa Clara, Calif., USA. This step is followed by a halo phosphorus implant which is performed in a EXTRION implanter, a tool manufactured by VARIAN, Palo Alto, Calif., USA to make the source and drain regions of the IGFETs of the P type in the support area. A RTA anneal is performed for dopant homogeneity, for instance in a AG tool manufactured by STEAG, San Jose, Calif., USA. Now a shallow implantation is performed in the PI 9500 implanter mentioned above with phosphorus atoms to create the source and drain regions of IGFETs of the N type in the array area. To fabricate these implanted regions, referenced 20′ and 20″ in the support and array areas respectively (generically 20) as shown in FIG. 2B, add much complexity to the conventional CB formation process in standard EDRAM/SDRAM silicon chips with 0.2 μm ground rules.

Once the Si₃N₄ spacers 19 and implanted regions 20 have been formed, the wafer is cleaned in a two-step process using a Huang solution in a CFM wet bench, a tool manufactured by Continuous Flow Machine Inc, West Chester, Pa., USA. The following operating conditions are appropriate.

| | |
|---|---|
| SCl: H₂O/NH₄OH/H₂O₂: 80:1.3:3.1 (in volume) | time: 2 min |
| H₂O flow (rinse): 3 gallons/min | time: 1 min |
| SC2: H₂O/HCl/H₂O₂ : 80:2.2:3.1 (in volume) | time: 2 min |
| H₂O flow (rinse): 3 gallons/min | time: 1 min |
| Temperature: 35° C. | |

This cleaning step is followed by the conformal deposition of another Si₃N₄ layer to coat the structure 10 top surface that has the double role of a diffusion barrier and an etch stop in the subsequent processing steps. This Si₃N₄ barrier layer can be deposited either by Plasma Enhanced Chemical Vapor Deposition (PECVD) or by Low Pressure Chemical Vapor Deposition (LPCVD).

If the PECVD technique is used, the deposition is typically performed in an AME 5000 reactor, a tool manufactured by APPLIED MATERIALS, using a SiH₄/NH₃ chemistry according to the process parameters recited below.

| | |
|---|---|
| Pressure: | 5.75 Torr |
| Temperature: | 480° C. |
| RF Power: | 340 Watt |
| NH₃ flow: | 0.0151/min |
| SiH₄ flow: | 0.0601/min |
| N₂ flow: | 41/min |
| Dep. rate: | 200 nm/min |

To have at least 5 nm between the GC lines 16 in the array area (the target), requires depositing a 25 nm thick Si₃N₄ layer at the top of the structure 10 surface measured on a product wafer (compared to the 15 nm that would be really necessary). As a matter of fact, this PECVD process gives a very non conformal deposition because it is very sensitive to the pattern factor effect. It is to be noted that this thickness of 5 nm cannot be corrected by further increasing the thickness of the deposited Si₃N₄ layer because this would increase the aspect ratio of the GC lines preventing the spaces therebetween to be properly filled with BPSG during a subsequent dielectric deposition step.

If alternatively the LPCVD technique is used, the Si₃N₄ material can be deposited in a TEL Alpha 8s, a tool manufactured by TOKYO ELECTRON LTD, Tokyo, Japan using a NH₃/DCS chemistry and the process parameters recited below.

| | |
|---|---|
| Pressure: | 200 mTorr |
| Temperature: | 715° C. |
| NH₃ flow: | 250 sccm |
| DCS flow: | 50 sccm |
| Wafer spacing: | 0.2 inch |
| Dep. rate: | 1 nm/min |
| Duration: | 3 H |

It is to be noted that, unlike the PECVD process which is poorly conformal, the LPCVD deposition does not present the thickness non-uniformity problem mentioned above but has other inconveniences.

The Si₃N₄ layer which is obtained by either technique is referenced 21 in FIG. 2C.

Next, the passivation inter-level dielectric (ILD) material, typically a boro-phospho-silicate-glass (BPSG), is deposited by LPCVD at 850° C. in a LAM 9800 plasma reactor, a tool sold by LAM RESEARCH, Fremont, Calif., USA, to form a BPSG layer which is used to fill the spaces between the GC lines 16. The chemistry consists of tri-ethyl-borate (TEB), phosphine (PH₃) and tetra-ethyl-ortho-silicate (TEOS) mixed with O₂ as a co-reactant. N₂ is the carrier gas as standard. The BPSG material is defined by its boron and phosphorous concentrations equal to 4.5% each. Structure 10 is then in-situ reflow annealed at 850° C. for 20 minutes to prevent void generation. The target is to obtain a thickness of the BPSG layer above diffusion/implanted regions 18/20 of about 65 nm (measured on a product wafer). The BPSG material is planarized by chemical-mechanical polishing in a EBARA CEP 022 polisher, a tool manufactured by Precision Machinery Group, Tokyo, Japan with standard operating conditions.

The thickness control is performed in-situ. The resulting structure is shown in FIG. 2D where the remaining parts of the BPSG layer after planarization bear numeral 22. This step is followed by a cleaning which aims to reduce contamination, for instance, in the CFM tool mentioned above and with the same operating conditions.

Now, referring to FIG. 2E, a TEOS SiO₂ layer 23 is blanket deposited onto the structure 10. Typically this deposition is performed by PECVD, for instance in the AME 5000 reactor mentioned above using a TEOS/O₂ chemistry as standard.

The target is to obtain a thickness of about 510 nm atop the structure 10 surface (measured on a product wafer). The wafer is cleaned in a FSI spray tool, an equipment manufactured by Fluoroware System Inc., Minneapolis, USA, with standard process parameters.

This last cleaning step is followed by a reflow anneal at 950° C. for 10 s in a N₂ atmosphere. At this stage of the CB contact fabrication process, diffusion and implanted regions 18 and 20 are merged in a single region referenced 18/20.

Borderless contact hole locations will be defined in the array area thanks to a photoresist mask comprised of a dual BARL (bottom anti-reflective layer)/photoresist layer as standard. For instance, a 90 nm thick layer of AR3 (a product manufactured by SHIPLEY, Malborough, Mass., USA) and a 625 nm thick layer of M10G (a photoresist manufactured by JAPAN SYNTHETIC RUBBER, Tokyo, Japan) are adequate in all 1 5 respects. These materials are successively deposited in a TEL ACT8, a tool manufactured by TOKYO ELECTRON LTD (TEL), Tokyo, Japan. Then, the photoresist layer is exposed in a Micrascan III, a tool manufactured by SILICON VALLEY GROUP (SVG), Wilton, Conn., USA according to the desired mask pattern and developed in said TEL ACT8 tool. Overlay and contact dimensions are checked. Borderless contact (CB) holes are now formed by anisotropic etching down to the diffusion regions 18/20 in the silicon substrate 11 according to a sequence of five steps that are all performed in the same chamber of a dry etcher, so that the CB etch is a fully integrated process. For instance, these five steps are conducted in a TEL 85 DRM plasma etcher, a tool manufactured by TOKYO ELECTRON Ltd., with standard operating conditions. They include the etching of the AR3 layer (not shown in FIG. 2E), the TEOS SiO₂ layer 23, the BPSG layer 22, the Si₃N₄ layer 21 and finally the SiO₂ gate layer 12 at the very bottom of the contact hole.

Now, the contact hole is filled with phosphorus doped polysilicon to form a contact plug. This step is performed either in a LPCVD VTR 7000 vertical furnace, a tool manufactured by SVG-THERMCO, San Jose, Calif., USA or the SACVD Centura reactor manufactured by APPLIED MATERIALS. This terminates the conventional borderless polysilicon (CB) contact fabrication process. The final structure is shown in FIG. 2F, where the CB polysilicon plug which contacts a diffusion region 18/20 bears numeral 24. With standard fabrication processes, diffusion regions 18/20 are very sensitive to different junction leakage effects caused by the chemical attack of the silicon substrate during the CB etch (referred to as “punchthrough” defects) and/or surface state change during ion implantation steps.

Etching the Si₃N₄ material of layer 21 when deposited by PECVD is very critical because it must accurately stop on the SiO₂ gate layer 12 despite its non-uniform thickness. With a thickness as low as 5 nm in nested regions in the array area, the detection of the underlying SiO₂ material exposition to the Si₃N₄ etch chemistry is very difficult. If the etching with the Si₃N₄ etch chemistry is excessive, the overetch is too important, causing said punchthrough defects and shorts between the CB contacts and the GC conductors (because the spacer integrity is degraded). On the contrary, if the Si₃N₄ etch is stopped too early, un-etched Si₃N₄ residues are left so that the SiO₂ material at the bottom of the contact hole will not be totally removed with the SiO₂ etch chemistry leading to “open” type defects (too highly resistive contacts). The Si₃N₄ layer 21 must withstand the process of etching through the TEOS/BPSG dual layer 23/22 while preserving the Si₃N₄ cap 15 integrity during the borderless contact hole formation process. The TEOS and BPSG etch steps require a selectivity greater than 6:1 (with respect to Si₃N₄) on patterned as well as on planar surfaces of structure 10 to ensure the integrity of the Si₃N₄ material of layer 21, spacers 19, and caps 15. Although the etch chemistry is adapted to anisotropically remove the Si₃N₄ material of layer 21, it is quite mandatory to have the Si₃N₄ layer 21 thickness of at least 15 nm to be sure to properly stop on the SiO₂ gate layer 12 top surface.

These inconveniences of the PECVD technique will be illustrated by reference to FIG. 3A which is a more detailed view of structure 10 at the stage of the fabrication depicted in FIG. 2C to distinguish more clearly the “array” and “support” areas of the silicon wafer. The conventional PECVD process leads to significant differences in the Si₃N₄ layer 21 thickness uniformity at the bottom of contact holes of about 75% between narrow spaces located in the nested regions (in the array area) and the wide spaces located in the isolated regions (in the support area). As apparent in FIG. 3A, the Si₃N₄ layer 21 thickness is about 5 nm in the first case compared to 25 nm in the second case. A thickness of 5 nm is not sufficient in the nested regions to ensure a good etch stop barrier during the borderless contact hole formation. When the Si₃N₄ material of layer 21 is etched, punchthrough defects (not shown in FIG. 3A) are created at the contact hole bottom into the so-called Active Areas (AAs). However, another particularity of PECVD deposited Si₃N₄ material is the high content of hydrogen atoms and pinholes (referenced H and 25 in FIG. 3A respectively) which directly results of the very low deposition temperature (480° C.) and the very high deposition rate (200 nm/min) of the SiH₄ chemistry respectively. PECVD deposited Si₃N₄ layers not only operate as a source of hydrogen atoms but is highly permeable to these atoms during subsequent aluminum metallurgy (e.g., word lines) anneals, making this deposition technique really advantageous to passivate the diffusion regions at the silicon substrate surface.

On the contrary, the LPCVD technique offers a very conformal Si₃N₄ material deposition but exhibits other drawbacks. As apparent in FIG. 3B, there is no substantial thickness difference between nested regions in the array area and isolated regions in the support area, so that the Si₃N₄ layer 21 thickness in the nested regions is sufficient to fully play its barrier role. Due to this highly desired thickness uniformity across the whole wafer, the Si₃N₄ layer 21 thickness can be reduced to 12 nm. Thanks to this lower thickness, the efficiency of the Si₃N₄ layer 21 during the selective etch performed during the borderless contact hole formation is strongly improved and the BPSG fill aspect ratio is reduced. As a consequence, the process window is improved. Unfortunately, Si₃N₄ layers deposited by LPCVD have a significant low hydrogen atom and pinhole concentration compared to PECVD deposited layers. Thermal budget considerations (which are determining to maintain the effective channel length L_{eff} of IGFETs within specifications) prevent any increase of the deposition temperature of 715° C. mentioned above, thus imposing a low deposition rate which prevents pinhole formation. On the other hand, the SiH₄/NH₃ chemistry used in the PECVD process could not be selected because it would give a non-uniform Si₃N₄ layer 21 thickness so that the NH₃/DCS chemistry is preferred for the specific LPCVD working conditions (hot wall reactor). But with this chemistry, the total amount of hydrogen atoms participating to the chemical mechanism is limited, reducing thereby the number of incorporated hydrogen atoms even more than the deposition temperature is lowered. The LPCVD process degrades junction leakage (reverse-biased junctions) more than the PECVD process as demonstrated by the parametric in-line test. At this stage of the borderless polysilicon contact fabrication process junction leakage are not healed. However, after aluminum metallurgy anneals that are performed in an hydrogen atmosphere, hydrogen atoms dissociate on the aluminum word lines surface in monatomic form to heal these junction leakage in a great extent.

In summary, the Si₃N₄ layer deposition step which is essential in the conventional borderless polysilicon contact fabrication process described by reference to FIGS. 2A to 2F is not satisfactory irrespective the deposition technique being used:

1. In case of PECVD, the Si₃N₄ etching step does not accurately stop on the SiO₂ gate layer surface at the bottom of contact holes in nested regions of the array area so that during the overetch there is a serious risk of “shorts” between adjacent GC lines and of a substantial attack of the silicon substrate in the contact hole bottom where the Si₃N₄ layer is thinner (5 nm), causing above mentioned punchthrough defects that are a major manufacturing yield issue.

2. In case of LPCVD, thanks to the good thickness uniformity, it is more likely that the etching stops well on the SiO₂ gate layer (however, if the overetch is insufficient, there is a serious risk of “opens” at the contact hole bottom). In addition, changes in the junction surface states cause junction leakage which are not fixable because with a LPCVD process, the deposited Si₃N₄ film has a low hydrogen atom content and is substantially impervious to hydrogen atoms (this phenomena is supposed to also occur with PECVD Si₃N₄ films but is greatly corrected at the subsequent aluminum metallurgy anneals). Likewise, these defects are manufacturing yield detractors.

Therefore, for different reasons, none of the above conventional Si₃N₄ barrier layer deposition process is acceptable in term of product manufacturing yield.

### SUMMARY OF THE INVENTION

It is therefore a primary object of the present invention to provide an improved method of depositing a conformal H-rich Si₃N₄ layer onto a patterned structure.

It is another object of the present invention to provide an improved method of depositing a conformal H-rich Si₃N₄ layer onto a patterned structure particularly well adapted to advanced EDRAM/SDRAM silicon chip manufacturing.

It is another object of the present invention to provide an improved method of depositing a conformal H-rich Si₃N₄ layer onto a patterned structure wherein the deposited layer has a uniform thickness across the wafer irrespective the array or support area.

It is another object of the present invention to provide an improved method of depositing a conformal H-rich Si₃N₄ layer onto a patterned structure wherein the deposited layer has a uniform that is independent of the integration density (pattern factor).

It is another object of the present invention to provide an improved method of depositing a conformal H-rich Si₃N₄ layer onto a patterned structure wherein the junction surface states change induced by the processing steps are corrected by the capacity of such a layer to supply hydrogen atoms and its permeability to these atoms.

It is still another object of the present invention to provide an improved method of depositing a conformal H-rich Si₃N₄ layer onto a patterned structure which allows to make borderless polysilicon contacts with diffusion regions without any risk of electrical fails (shorts, opens and junction leakage).

It is still another object of the present invention to provide an improved method of depositing a conformal H-rich Si₃N₄ layer onto a patterned structure which allows to open borderless contact holes across the whole wafer with an absolute certainty, maintaining thereby the manufacturing yield at a high and constant level.

It is still another object of the present invention to provide an improved method of depositing a conformal H-rich Si₃N₄ layer onto a patterned structure in the fabrication of borderless polysilicon contacts which minimizes the thermal budget to prevent spreading of diffusion regions to keep constant the IGFET effective channel length L_{eff}.

It is still another further object of the present invention to provide an improved method of depositing a conformal H-rich Si₃N₄ layer onto a patterned structure which reduces the deposition cycle time, a critical parameter of the borderless polysilicon contact fabrication process in advanced EDRAM silicon chips.

The accomplishment of these and other related objects is first achieved by the improved method of depositing a conformal H-rich Si₃N₄ layer onto a patterned structure according to a first embodiment of the present invention which comprises the steps of:

a) providing a patterned structure comprising a silicon substrate coated with a thin SiO₂ gate layer having gate conductor (GC) lines formed thereon and having at least one diffusion region formed between two adjacent GC lines; and

b) depositing a conformal H-rich Si₃N₄ layer onto the structure in a Rapid Thermal Chemical Vapor Deposition (RTCVD) reactor using a Si precursor based chemistry at a temperature of about 600° C. to about 950° C. and a pressure of about 50 Torr to about 200 Torr.

The present invention also encompasses the improved method of depositing a conformal H-rich Si₃N₄ layer onto a patterned structure according to a second embodiment of the present invention which comprises the steps of:

a) providing a patterned structure comprising a silicon substrate coated with a thin SiO₂ gate layer having gate conductor (GC) lines formed thereon and having at least one diffusion region formed between two adjacent GC lines; and

b) depositing a conformal H-rich Si₃N₄ layer onto the structure in a Low Pressure Chemical Vapor Deposition (LPCVD) furnace using a Si precursor based chemistry at a temperature of about 640° C. to about 700° C. and a pressure of about 0.2 Torr to about 0.8 Torr.

Finally, the present invention further encompasses the improved method of fabricating a borderless polysilicon contact with a diffusion region in a silicon substrate which comprises the steps of:

a) providing a structure comprising a silicon substrate coated with a thin SiO₂ gate layer having gate conductor (GC) lines formed thereon, wherein the conductive portion of said GC lines is laterally coated by a thin Si₃N₄ spacer and the top portion of said GC lines is coated by a Si₃N₄ cap, and wherein at least one diffusion region formed in said substrate is exposed between two adjacent GC lines;

b) depositing a conformal H-rich Si₃N₄ layer onto the structure, either in a Rapid Thermal Chemical Vapor Deposition (RTCVD) reactor using a Si precursor based chemistry at a temperature of about 600° C. to about 950° C. and a pressure of about 50 Torr to about 200 Torr, or in a Low Pressure Chemical Vapor Deposition (LPCVD) furnace using a Si precursor based chemistry at a temperature of about 640° C. to about 700° C. and a pressure of about 0.2 Torr to about 0.8 Torr;

c) depositing a layer of BPSG material in excess onto the structure to fill the spaces between the GC lines;

d) planarizing the BPSG material by chemical-mechanical polishing to remove the BPSG down to approximately the Si₃N₄ cap surface;

e) depositing a passivating layer of TEOS SiO₂ onto the structure;

f) defining a photolithography mask to expose contact hole locations;

g) anisotropically dry etching the TEOS SiO₂, BPSG, Si₃N₄ and SiO₂ materials in sequence to expose the diffusion region to form the contact hole; and

h) depositing doped polysilicon to fill the contact hole and create the borderless polysilicon contact with said diffusion region.

The above method has significant advantages in terms of product reliability (lower contact resistance, larger process window, etc.), throughput improvements and process flow simplification.

The novel features believed to be characteristic of this invention are set forth in the appended claims. The invention itself, however, as well as other objects and advantages thereof, may be best understood by reference to the following detailed description of an illustrated preferred embodiment to be read in conjunction with the accompanying drawings.

### BRIEF DESCRIPTION OF THE DRAWINGS

FIG. 1 shows the semiconductor structure at the initial stage of the borderless polysilicon contact (CB) fabrication process.

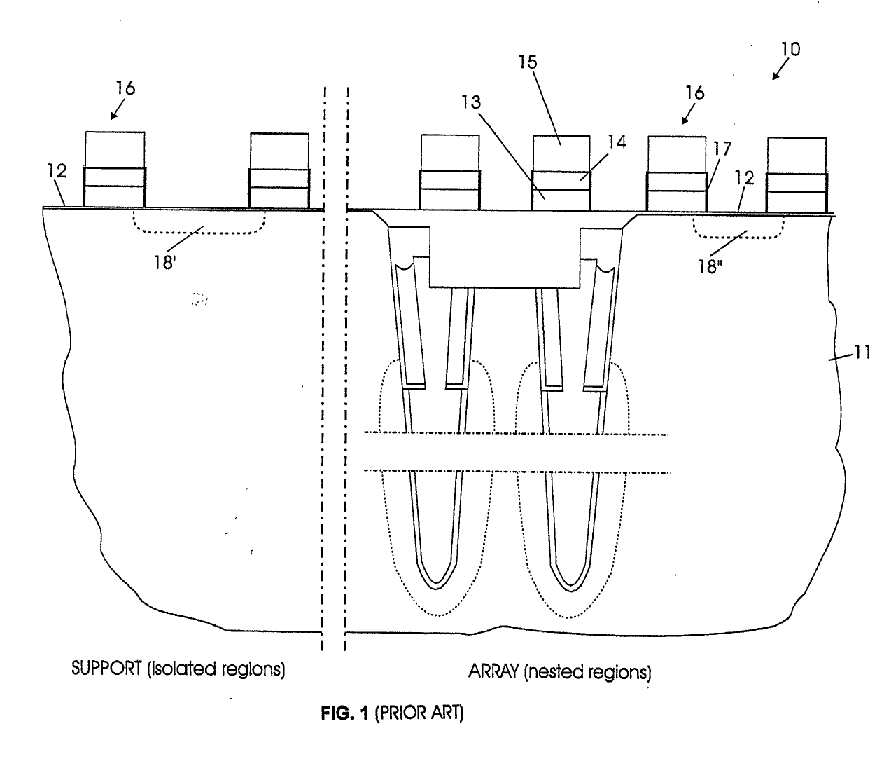

FIGS. 2A-2F show the structure of FIG. 1 undergoing the essential steps of a conventional borderless polysilicon contact (CB) fabrication process.

FIGS. 3A and 3B are enlarged views of FIG. 2C to illustrate the drawbacks of the POR (Plan Of Record) PECVD and LPCVD techniques respectively when they are used for the Si₃N₄ barrier layer deposition step in said conventional CB fabrication process.

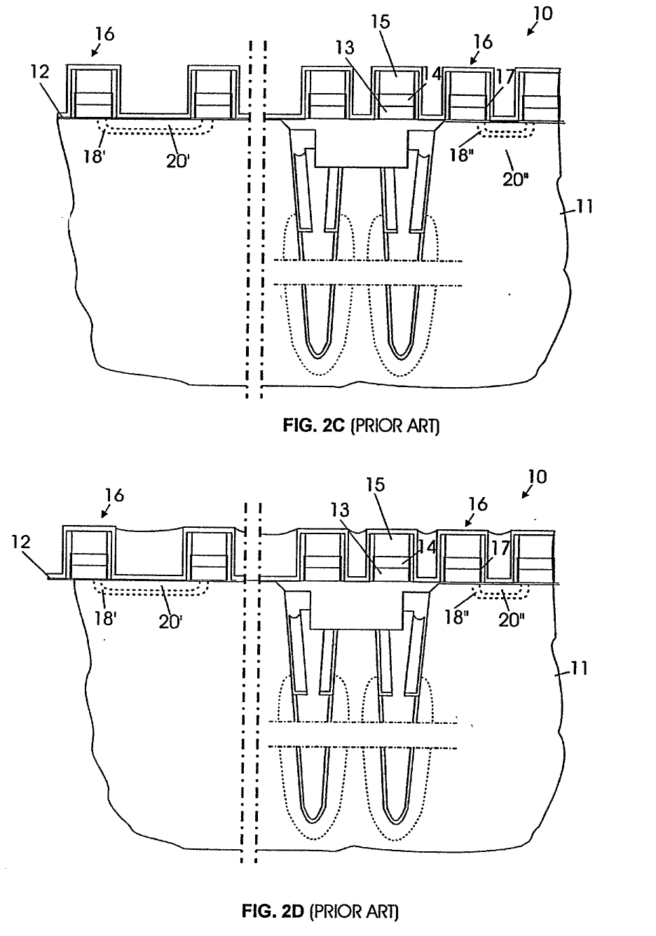

FIG. 4 is an enlarged view of FIG. 2C when the Si₃N₄ barrier layer is deposited according to the method of the present invention.

FIG. 5 are graphs showing the hydrogen atom concentrations vs the sample thickness obtained by SIMS measurements to illustrate the significant improvements brought up by the method of the present invention when compared to the POR deposition techniques.

FIG. 6A is a graph showing peak intensity as a function of the wave number to illustrate to which chemical compound the hydrogen atoms are linked when the POR LPCVD technique is used.

FIG. 6B is a graph showing peak intensity as a function of the wave number to illustrate to which chemical compound the hydrogen atoms are linked when the POR PECVD technique is used.

FIG. 6C is a graph showing peak intensity as a function of the wave number to illustrate to which chemical compound the hydrogen atoms are linked when the first embodiment (RTCVD based technique) of the method of the present invention is used.

FIG. 6D is a graph showing peak intensity as a function of the wave number to illustrate to which chemical compound the hydrogen atoms are linked when the second embodiment (LPCVD based technique) of the method of the present invention is used.

FIG. 7A is a graph showing the junction leakage current due to the punchthrough defects for IGFETs of the N type for the POR PECVD technique and the two embodiments of the method of the present invention for different lots of wafers.

FIG. 7B is a graph showing the junction leakage due to the junction surface state defects for IGFETs of the N type for the POR LPCVD technique and the two embodiments of the method of the present invention for different lots of wafers.

### DESCRIPTION OF THE PREFERRED EMBODIMENTS

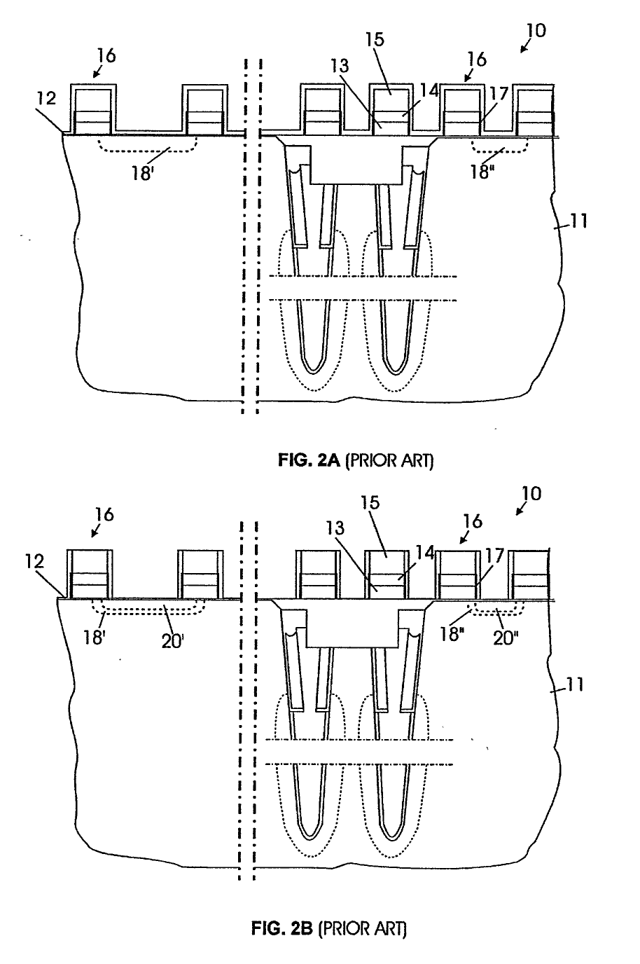

The improved method of forming a conformal H-rich Si₃N₄ layer in the borderless polysilicon contact fabrication process in accordance with the present invention will be now described. It aims to replace the POR PECVD and LPCVD deposition techniques described above by reference to FIG. 2C. Such a layer will be capable of fully playing the role of a barrier and acting as a good etch stop layer during the borderless contact hole formation while preserving the GC lines 16 sidewall integrity. In addition, this layer will supply hydrogen atoms and will be permeable to them during subsequent aluminum metallurgy anneals. As a result, the thermal budget will be kept as low as possible. In other words, the method of the present invention aims to combine the advantages of the POR PECVD and LPCVD techniques described above without their respective inconveniences.

First Embodiment

The method of depositing a conformal H-rich Si₃N₄ barrier layer is based on the SiH₄/NH₃ chemistry of the POR PECVD and the high temperature of the POR LPCVD using specific operating conditions that have been developed by the inventors to have the deposition performed at a high pressure. Because the deposition is performed at a high temperature, it is essential that the run time be as short as possible. As a result, a low thermal budget and dopant diffusion kinetics to form diffusion regions 18/20 are achieved, so that the effective channel length L_{eff} and diffusion region junction resistance of IGFETs are not detrimentally affected. The method uses the Rapid Thermal CVD (RTCVD) technique (also referred to as Sub Atmospheric CVD or SACVD in short) which has been known so far only for the deposition of polysilicon or tungsten silicide, but not for the deposition of Si₃N₄ material. For instance, the AME SACVD/RTCVD Centura tool mentioned above for polysilicon deposition can be adapted to meet the present Si₃N₄ deposition needs. This commercially available cold wall single wafer reactor was thus internally modified to implement new gas lines (NH₃, NF_{3,} etc.). In addition, a new susceptor conditioning was defined according to EP Application No. 00480069.4, titled “A Multideposition SACVD Reactor,” filed Jul. 25, 2000, the disclosure of which is incorporated herein by reference, in order to get repeatable characteristics of the deposited Si₃N₄ material.

A specific conditioning of the susceptor is required because it is made of carbon and NF₃ which is the preferred cleaning chemical compound that is capable of removing the Si₃N₄ material deposited on the reactor quartz walls and the susceptor is known to be very aggressive to carbon. The carbon susceptor protection against NF₃ chemical is first ensured by a coating of polysilicon (about 4 μm thick) performed on the susceptor bottom with a SiH₂Cl₂ (DCS) chemistry. In fact, this coating plays a double role: it not only protects the susceptor bottom, it also allows determination of its temperature by a measure of its emissivity. Then, another polysilicon coating (about 1.5 μm thick) is performed on the susceptor top with a SiH₄ chemistry. As such, the carbon susceptor is now ready for Si₃N₄ deposition in the AME Centura tool.

When a large number of wafers have been processed in the chamber, it becomes out of specifications, so that an in-situ cleaning of the chamber is required. The following sequence is appropriate. First, a NF₃ chemical clean is done to remove the Si₃N₄ material deposited on the reactor cold wall and the susceptor. Then, a HCl clean is done to remove the totality of the polysilicon coating because it has been damaged and the above described protection procedure is then repeated again to prepare the susceptor for a new series of runs.

It is now possible to use the SACVD Centura tool with a SiH₄ based chemistry at a temperature and a pressure in the 600-950° C. and 50-200 Torr ranges respectively.

More specifically, when the AME Centura tool is used with a SiH₄/NH₃ chemistry, Si₃N₄ barrier layer 21 fully expected characteristics are obtained by setting the temperature and the pressure at about 785° C. and 90 Torr respectively. Appropriate working conditions are given below.

| | |
|---|---|
| Pressure: | 90 Torr |
| Temperature: | 785° C. |
| SiH₄ flow: | 0.21/min |
| NH₃ flow: | 31/min |
| N₂ (carrier) flow: | 101/min |
| Dep. rate: | 90 nm/min |
| Duration: | 3 min |

The thickness and reflective indices of the Si₃N₄ layer 21 are monitored on a blanket wafer after each 10th RTCVD run. The wafer exposure to 785° C. is limited to about a very few minutes (3 min in the instant case) which prevents the diffusion region 18/20 spreading, and thus any effective channel length change. As a final result, array Vt shift failures are minimized.

Second Embodiment

A LPCVD equipment (which is a hot wall wafer batch reactor) can also be used. In such a batch furnace, the standard NH₃/SiH₂Cl₂ (DCS) chemistry has also given the expected results, very close to those obtained with the SiH₄/NH₃ chemistry by lowering the deposition temperature below 700° C., rising the total pressure at about 0.5 Torr and enriching gas phase with the SiH₂Cl₂ reactant to 3:1 ratio. However, the DCS reactant can be enriched in the NH₃/DCS mixture up to ratio of about 1:1 (the preferred ratio).

Using the TEL Alpha 8s tool mentioned above, the following working conditions are adequate.

| | |
|---|---|
| Pressure: | 0.5 Torr |
| Temperature: | 650° C. |
| NH₃ flow: | 0.1201/min |
| DCS flow: | 0.1201/min |
| Dep. Rate: | 0.7 nm/min |
| Wafer spacing: | 0.2 inch |
| Duration: | 3 H |

The new LPCVD working conditions fulfill Si₃N₄ barrier layer desired characteristics mentioned above; it is conformal, i.e. it has an uniform thickness all across the wafer thus forming a good etch stop, and it has a sufficient amount of hydrogen atoms therein.

The very low deposition rate of the LPCVD process (about 0.7 nm/min) has a significant impact on cycle time, but if it represents a penalty for OEM manufacturing (e.g. EDRAM chips) it is greatly advantageous in fabricating SDRAM chips because it is a mass production. In the same working conditions, the SiH₄/NH₃ chemistry has a higher deposition rate but is not recommended in a batch furnace because it induces stresses and thickness non-uniformity in the Si₃N₄ deposited material.

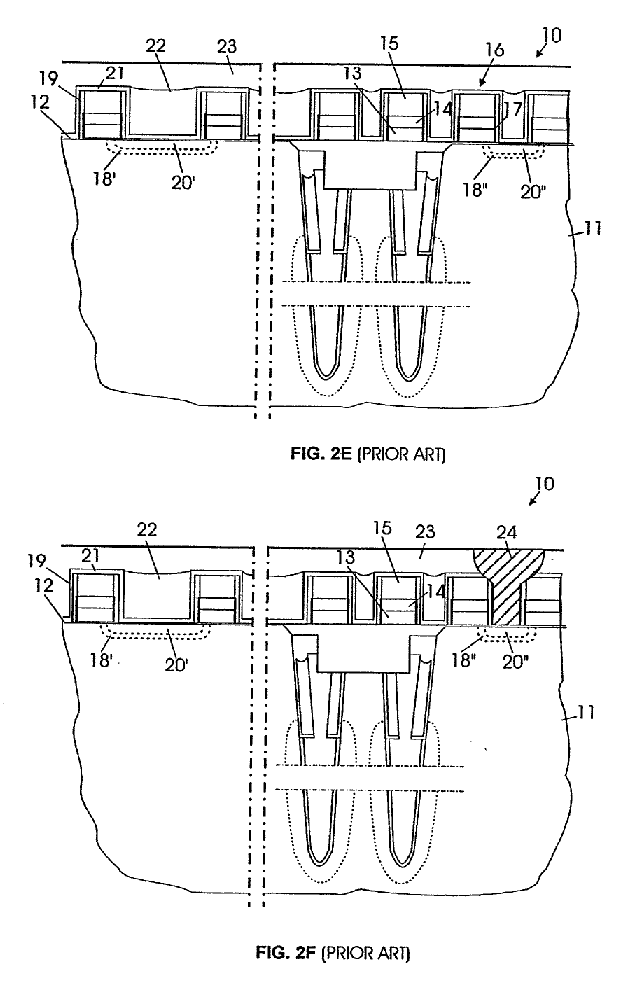

Irrespective the deposition technique, a very conformal H-rich Si₃N₄ layer is obtained with no substantial difference between nested and isolated regions as shown in FIG. 4. As a matter of fact, equivalent results have been obtained with both techniques on product wafers in terms of junction leakage.

Other chemistries, such as a ternary NH₃/SiH₄/DCS mixture, could be used as well. Likewise, other dielectric materials such as SiON, could also be deposited still in accordance with the method of the present invention.

The mechanism at the base of the present invention may be understood if one considers that the reactants cracking which gives free radicals whose dissociation mainly occurs close to the wafer surface favoring hydrogen atom incorporation into the Si₃N₄ layer. This mechanism hypothesis has been verified with SIMS, IR and FTIR analysis to identify the most preponderant hydrogen atom precursor.

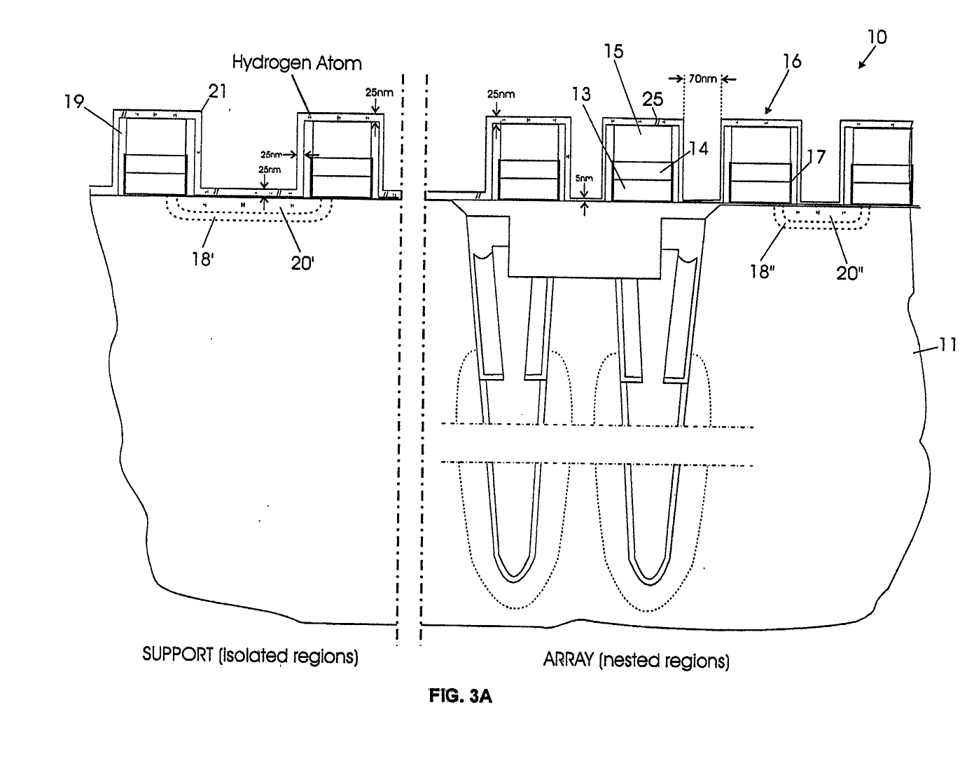

FIG. 5 shows SIMS results obtained using an IMS 6F, a tool manufactured by CAMECA, Courbevoie, France with the following operating conditions.

| | |
|---|---|
| Outgasing: | 12 H |
| Vacuum level: | 1E-10 Torr |
| Current: | 10 nA |
| Scanning: | 100 μm |

The graphs show the hydrogen atom concentration (H) in normalized counts per second (c/s) as a function of the sample thickness Th (in Å) and are illustrative of the amount of hydrogen atoms in the Si₃N₄ deposited material. Turning to FIG. 5, curves 26 and 27 respectively show the results obtained with the POR PECVD and LPCVD processes of the prior art. On the other hand, curves 28 and 29 respectively show the results obtained with the RTCVD and LPCVD processes according to the method of the present invention. The general aspect of the two sets of curves is different because samples of different thicknesses were used in the experiments. The improvement between the POR LPCVD process and the LPCVD process of the present invention is clear from the comparison between curves 27 and 29. The improvement is less significant between the POR PECVD and the RTCVD processes (curves 26 and 28) because the POR PECVD process is already quite good in that respect.

TABLE I below shows ellipsometry IR results obtained on a GESP 5 DUVNIR (Deep UV Near Infra Red Gonio-Spectro Ellipsometer) commercially available from SOPRA, Bois-Colombes, France under following operating conditions:

Spectral domain: 193 nm to 900 nm (or 6.224 eV to 1.524 eV)

Incidence angle: 65° and 75°

Tested area: some mm² at the center of wafers.

Step: 0.05 eV

using the BEMA (Bruggemann Effective Medium Approximation), valid for films without oxygen, to recalculate the Si₃N₄ layer 21 thickness and the refractive index in order to quantify (in relative mode) the hydrogen atom concentration (in % of volume) contained therein.

TABLE I

| Process | Thickness (Å) | Refractive Index | H Concentration |
|---|---|---|---|
| POR PECVD | 426 | 1.962 | 0.042 |
| POR LPCVD | 605 | 1.977 | 0.016 |
| RTCVD | 398 | 1.970 | 0.048 |
| LPCVD | 398 | 2.019 | 0.040 |

Beyond expected, POR PECVD, RTCVD and LPCVD processes lead to similar results in terms of hydrogen atom concentration (H) which is not totally consistent with above SIMS measurements. This is probably due to the approximations of the BEMA method which is less accurate than the SIMS analysis technique. On the other hand, FTIR measurements are important to understand the origin (SiH₄ or NH₃) of the hydrogen atoms. The wave numbers for the N—H, Si—H, etc., links are given in TABLE II below.

TABLE II

| | N-H | Si-H | N-H | Si-O | Si-N |
|---|---|---|---|---|---|
| Wave | 3342 | 2189 | 1190 | 1060 | 836 |
| number | | | | | |

λ (cm⁻¹)

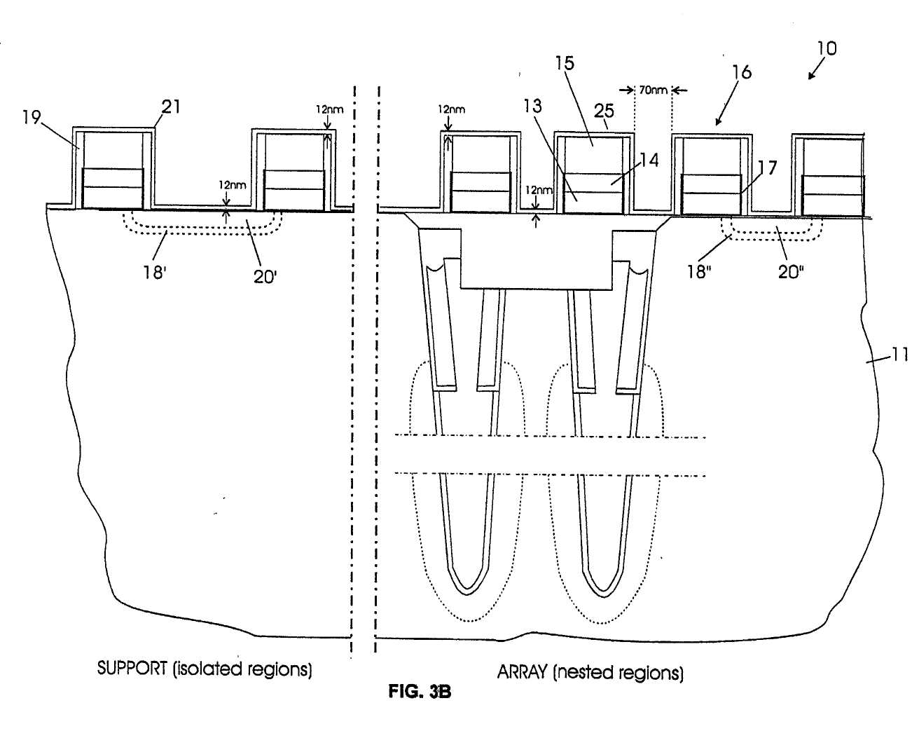

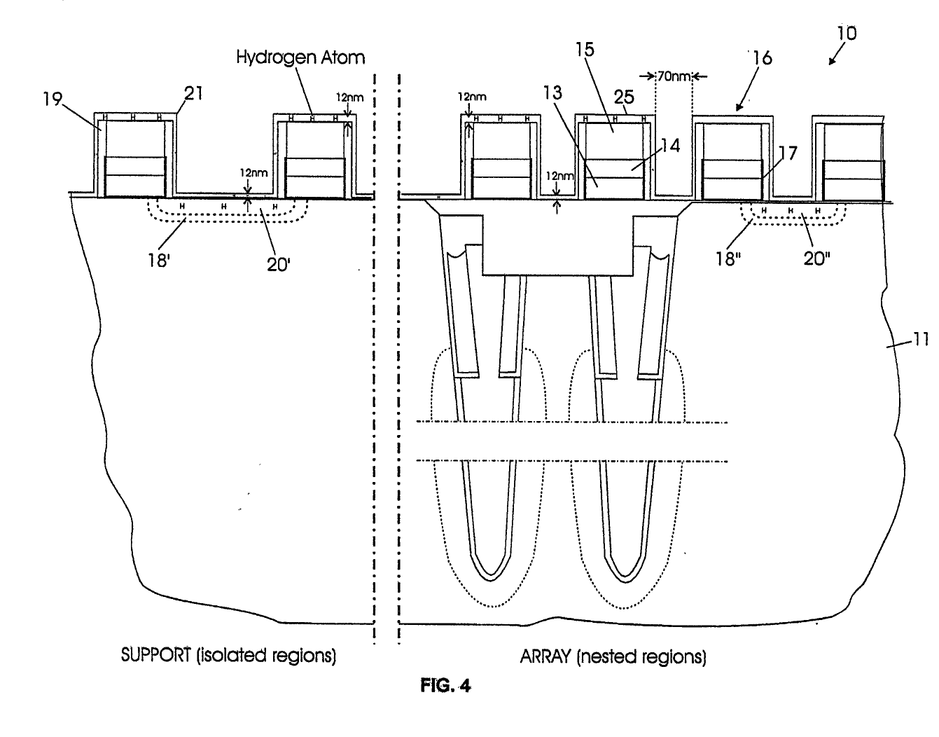

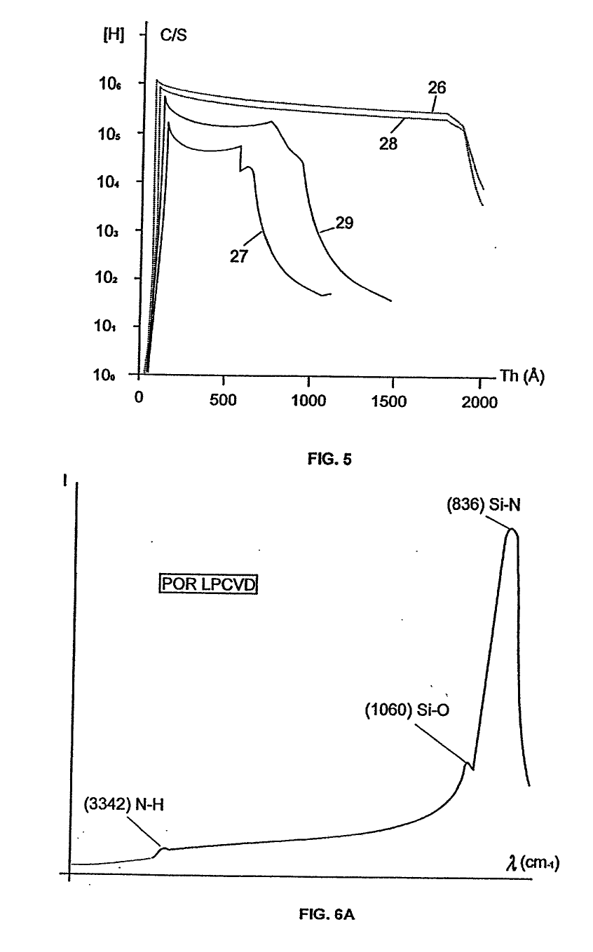

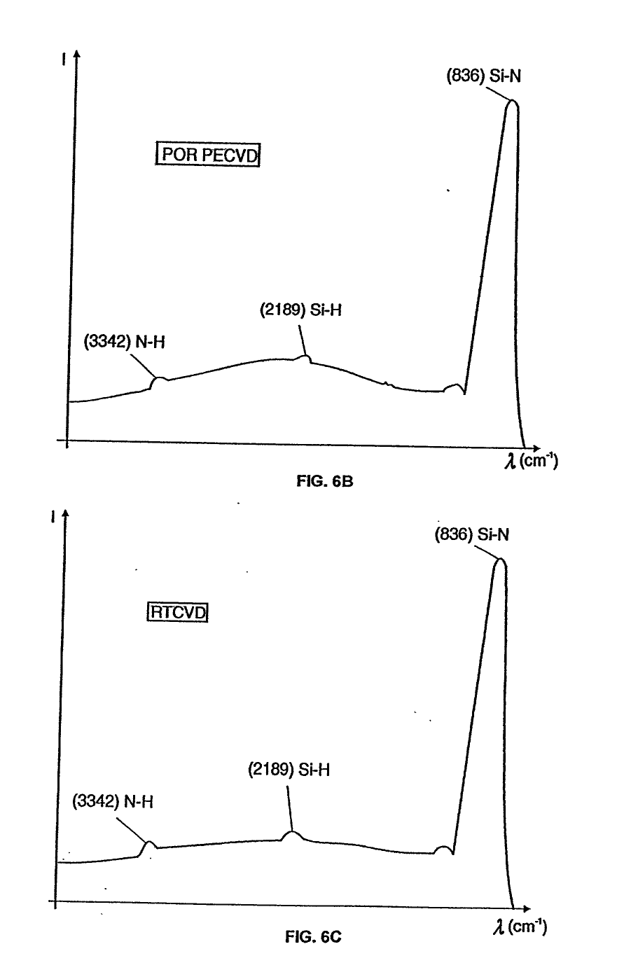

FIG. 6A is a graph showing the FTIR spectrum for the POR LPCVD process when a NH₃/DCS chemistry is used. FIG. 6A shows the peak intensity I as a function of the wave number 1 (in cm⁻¹) to illustrate to which chemical compound the hydrogen atoms are linked. As apparent in FIG. 6A, FTIR measurements show only one absorption peak corresponding to an hydrogen link coming from the NH₃ precursor (see peak N—H at 3342 cm⁻¹). No peak corresponding to a Si—H link from the other precursor DCS can be observed.

FIG. 6B is a graph showing the FTIR spectrum for the POR PECVD process when the NH₃/SiH₄ chemistry is used. FIG. 6B shows the peak intensity I as a function of the wave number λ to illustrate to which chemical compound the hydrogen atoms are linked. FTIR measurements now show two absorption peaks corresponding to a hydrogen link coming from the NH₃ precursor (see peak N—H at 3342 cm⁻¹) and from SiH₄ (see peak Si—H at 2189 cm⁻¹).

FIG. 6C is a graph showing the FTIR spectrum for the first embodiment of the present invention based upon RTCVD (or SACVD) with a NH₃/SiH₄ chemistry. FIG. 6C shows similar results when compared those depicted in FIG. 6B, because this process incorporates as much hydrogen atoms as the POR PECVD process because it uses the same chemistry, but it is much more conformal.

FIG. 6D is a graph showing the FTIR spectrum for the second embodiment of method of the present invention. FIG. 6D still shows the peak intensity as a function of the wave number to illustrate to which chemical compound the hydrogen atoms are linked. FTIR measurements show a new absorption peak at 2189 cm⁻¹ which corresponds to the Si—H link of the DCS precursor in addition to the peak corresponding to the N—H link (3342 cm⁻¹).

In conclusion, the results obtained by the different chemical analysis techniques (SIMS, IR, and FTIR) showed that the variations of hydrogen atoms into the Si₃N₄ layer mostly depends upon the Si precursor. To produce a H-rich Si₃N₄ layer, SiH₄ appears more favorable than DCS (SiH₂Cl₂) and certainly much more than TCS (SiCl₄) not tested in the present work. The rate of hydrogen atom incorporation is varying as a function of the H/Cl ratio of the Si precursor molecule and is independent of the working conditions of the chemistry being used (NH₃/SiH₄ or NH₃/DCS) which are very different in terms of pressures, temperatures and gas flows. Replacing DCS by SiH4 results in an increase of SiH free radicals in the gaseous phase and thus in the Si₃N₄ layer because there is no possible recombination with the chlorine coming from DCS (or TCS) dissociation to form HCl gas.

In the particular case of the second embodiment (LPCVD), despite DCS use, the hydrogen atom concentration increase is due to two contributors: a lower temperature and an gas phase enriched in DCS. A higher pressure is required to have an acceptable deposition rate to meet the manufacturing needs (cycle time, cost, etc.). Note that, for DRAM mass production, the working conditions of the second embodiment are cheaper.

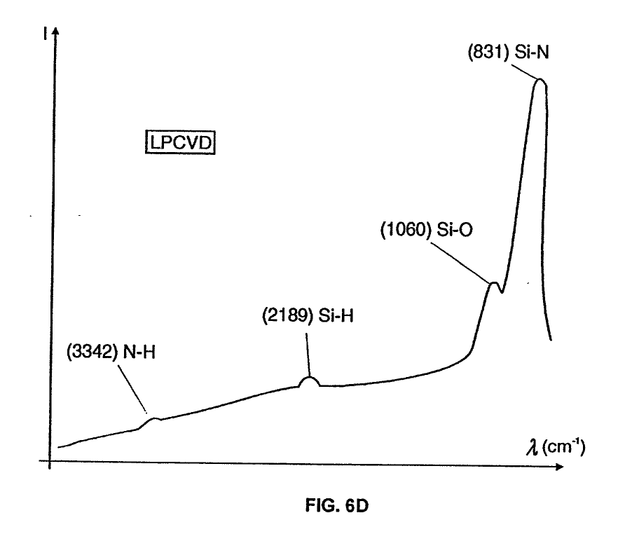

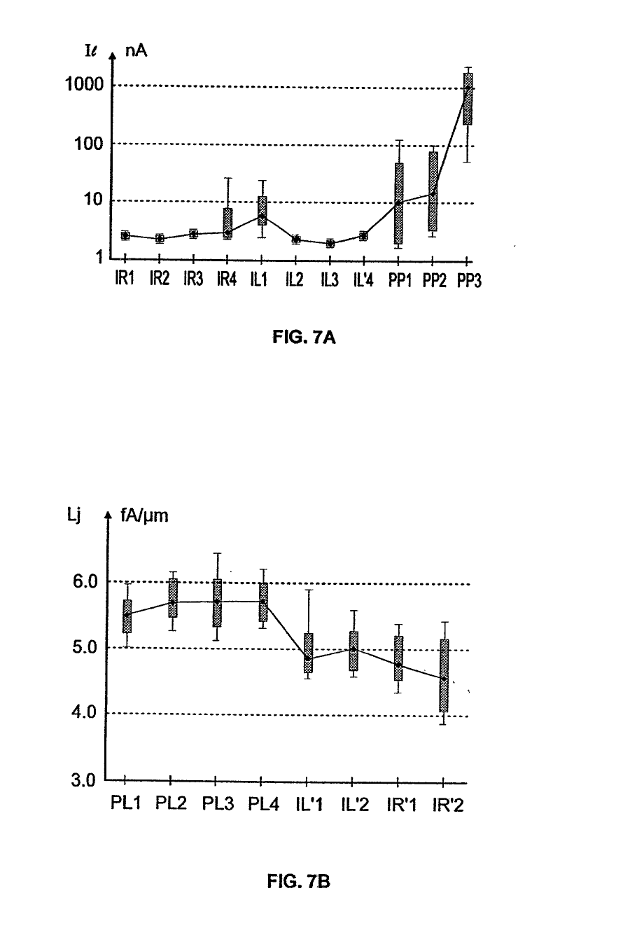

FIGS. 7A and 7B show results that were obtained with product wafers with the two embodiments of the present invention for the sake of comparison with the POR processes.

FIG. 7A is a graph showing the junction leakage current I┐ (in nA) caused by punchthrough defects for IGFETs of the N type pertaining to different lots of wafers. Leakage currents are shown for three lots (PP1 to PP3) processed with the POR PECVD technique and four lots (IR1 to IR4 and IL1 to IL4) processed with the RTCVD and LPCVD techniques respectively according to the method of the present invention. As apparent in FIG. 7A, in the latter case, the junction leakage current is significantly lower than with the POR PECVD, demonstrating thereby the role of the present invention in preventing silicon attack during the CB etch.

FIG. 7B is a graph showing the junction leakage Lj (in fA/μm) due to the junction surface state defects for IGFETs of the N type for different lots of product wafers. The junction leakage is shown for four lots processed with the POR LPCVD technique (PL1 to PL4) and two lots (IR′1, IR′2 and IL′1, IL′2) respectively processed with the RTCVD and LPCVD techniques according to the method of the present invention. As apparent in FIG. 7B, in the two latter cases, the junction leakage is significantly lower than with the POR PECVD, demonstrating thereby the role of the present invention in passivating the surface states. Finally, the number of pinholes which are often coming from fast reactions, is reduced compared to PECVD technique because the higher deposition temperature is favorable to hydrogen atoms migration onto the wafer surface. For the LPCVD technique which uses DCS, the amount of incorporated hydrogen atoms is lower but sufficient to heal junction leakage.

In conclusion, electrical measurements conducted on 256 Mbit DRAM chips have clearly shown that a conformal H-rich Si₃N₄ barrier layer solves different junction leakage problems and optimizes SDRAM device characteristics because the total thermal budget is reduced in both embodiments.

While the invention has been particularly described with respect to preferred embodiments thereof it should be understood by one skilled in the art that the foregoing and other changes in form and details may be made therein without departing from the spirit and scope of the invention.

What is claimed:

1. A method of depositing a conformal H-rich Si₃N₄ layer onto a patterned structure comprising the steps of:
a) providing a patterned structure comprising a silicon substrate coated with a thin SiO₂ gate layer having gate conductor (GC) lines formed thereon and having at least one diffusion region formed between two adjacent GC lines; and
b) depositing a conformal H-rich Si₃N₄ layer onto said structure in a Rapid Thermal Chemical Vapor Deposition (RTCVD) reactor using a Si precursor based chemistry at a temperature of about 600° C. to about 950° C. and a pressure of about 50 Torr to about 200 Torr.

2. The method of claim 1 wherein said Si precursor based chemistry is SiH₄.

3. The method of claim 1 wherein said Si precursor based chemistry is a SiH₄/NH₃ mixture.

4. The method of claim 3 wherein said deposition is performed in an AME Centura tool with a carbon susceptor protected against NF_{3,} at a pressure of about 90 Torr, at a temperature of about 785° C., with a SiH₄ flow of about 0.2 1/min, with a NH₃ flow of about 3 1/min, with a N₂ flow of about 10 1/min, and at a deposition rate of about 90 nm/min.

5. A method of depositing a conformal H-rich Si₃N₄ layer onto a patterned structure comprising the steps of:
a) providing a patterned structure comprising a silicon substrate coated with a thin SiO₂ gate layer having gate conductor (GC) lines formed thereon and having at least one diffusion region formed between two adjacent GC lines; and
b) depositing a conformal H-rich Si₃N₄ layer onto said structure in a Low Pressure Chemical Vapor Deposition (LPCVD) furnace using a Si precursor based chemistry at a temperature of about 640° C. to about 700° C. and a pressure of about 0.2 Torr to about 0.8 Torr.

6. The method of claim 5 wherein said Si precursor based chemistry is DCS.

7. The method of claim 5 wherein said Si precursor based chemistry is a NH₃/DCS mixture.

8. The method of claim 6 wherein said deposition is performed in a TEL Alpha 8s tool at a pressure of about 0.5 Torr, at a temperature of about 650° C., with a NH₃ flow of about 0.120 1/min, with a DCS flow of about 0.120 1/min, and at a deposition rate of about 0.7 nm/min.

9. The method of claim 5 wherein said Si precursor based chemistry is a NH₃/SiH₄/DCS mixture.

10. A method of fabricating a borderless polysilicon contact with a diffusion region in a silicon substrate which comprises the steps of:
a) providing a structure comprising a silicon substrate coated with a thin SiO₂ gate layer having gate conductor (GC) lines formed thereon, wherein the conductive portion of said GC lines is laterally coated by a thin Si₃N₄ spacer and the top portion of said GC lines is coated by a Si₃N₄ cap, and wherein at least one diffusion region formed in said substrate is exposed between two adjacent GC lines;
b) depositing a conformal H-rich Si₃N₄ layer onto said structure, either in a Rapid Thermal Chemical Vapor Deposition (RTCVD) reactor using a Si precursor based chemistry at a temperature of about 600° C. to about 950° C. and a pressure of about 50 Torr to about 200 Torr, or in a Low Pressure Chemical Vapor Deposition (LPCVD) furnace using a Si precursor based chemistry at a temperature of about 640° C. to about 700° C. and a pressure of about 0.2 Torr to about 0.8 Torr;
c) depositing a layer of BPSG material in excess onto said structure to fill spaces between said GC lines;
d) planarizing said BPSG material by chemical-mechanical polishing to remove said BPSG down to approximately the Si₃N₄ cap surface;
e) depositing a passivating layer of TEOS SiO₂ onto said structure;
f) defining a photolithography mask to expose contact hole locations;
g) anisotropically dry etching said TEOS SiO_{2,} BPSG, Si₃N₄ and SiO₂ materials in sequence to expose said diffusion region to form said contact hole; and
h) depositing doped polysilicon to fill said contact hole and create said borderless polysilicon contact with said diffusion region.
